(19) United States
(12) Patent Application Publication
(10) Pub. No.: US 2019/0033649 A1
(43) Pub. Date: Jan. 31, 2019

(54) DISPLAY DEVICE

(71) Applicant: Japan Display Inc., Minato-ku (JP)

(72) Inventor: Kentaro OKUYAMA, Minato-ku (JP)

(73) Assignee: Japan Display Inc., Minato-ku (JP)

(21) Appl. No.: 16/038,857

(22) Filed: Jul. 18, 2018

(30) Foreign Application Priority Data
Jul. 25, 2017 (JP) 2017-143975

(51) Int. Cl. G02F 1/137; G02F 1/1368; G02F 1/1335; G02F 1/1339; G02F 1/1343; G02F 1/1333; G02F 1/1337; G02F 1/1362; G09G 3/36; H01L 27/32

(52) U.S. Cl. CPC G02F 1/13725; G02F 1/1368; G02F 1/133528; G02F 1/133514; G02F 1/1339; G02F 1/134336; G02F 2201/123; G02F 1/133345; G02F 1/1337; G02F 1/136277; G09G 3/3677; H01L 27/3246; G02F 2201/121; G02F 1/133553

(57) ABSTRACT

According to an aspect, a display device includes: a display portion configured to emit display light; an optical element having a first surface and a second surface and configured to transmit or reflect the display light, the second surface being on an opposite side of the first surface and facing the display portion; a reflective element facing the second surface of the optical element and configured to retroreflect the display light reflected at the optical element; and a transmittance control element configured to transmit the display light at a different transmittance in accordance with a position at which the display light passes through the transmittance control element.

### CROSS-REFERENCE TO RELATED APPLICATIONS

This application claims priority from Japanese Application No. 2017-143975, filed on Jul. 25, 2017, the contents of which are incorporated by reference herein in its entirety.

### BACKGROUND

### 1. Technical Field

The present disclosure relates to a display device.

### 2. Description of the Related Art

As one example of a display device that displays images in the air, Japanese Patent Application Laid-open Publication No. 2011-253128 discloses an imaging device that displays images by forming the images in the air. In such an imaging device, display light emitted from a display portion is specularly reflected at a reflective polarizing filter and enters a retroreflector. The display light retroreflected at the retroreflector passes through the reflective polarizing filter and forms an image at a position symmetrical to the display portion about the polarizing filter.

In such a display device, the display light emitted from the display portion is reflected a plurality of times before forming an image and diffusion may occur upon each reflection. The diffusion may lower contrast and deteriorate display quality.

### SUMMARY

According to an aspect of the present disclosure, a display device includes: a display portion configured to emit display light; an optical element having a first surface and a second surface and configured to transmit or reflect the display light, the second surface being on an opposite side of the first surface and facing the display portion; a reflective element facing the second surface of the optical element and configured to retroreflect the display light reflected at the optical element; and a transmittance control element configured to transmit the display light at a different transmittance in accordance with a position at which the display light passes through the transmittance control element.

### BRIEF DESCRIPTION OF THE DRAWINGS

FIG. 1 is a diagram illustrating an exemplary configuration of a display device according to a first embodiment of the present disclosure;

FIG. 2 is a sectional view schematically illustrating a sectional structure of a display panel;

FIG. 3 is a sectional view schematically illustrating a sectional structure of a reflective element;

FIG. 4 is a sectional view schematically illustrating a sectional structure of a transmittance control element;

FIG. 5 is a block diagram illustrating an exemplary configuration of the display device;

FIG. 6 is a block diagram illustrating an exemplary configuration of a display device according to a modification of the first embodiment;

FIG. 7 is a diagram illustrating an exemplary configuration of a display device according to a second embodiment of the present disclosure;

FIG. 8 is a diagram illustrating an exemplary configuration of a display device according to a third embodiment of the present disclosure;

FIG. 9 is a diagram illustrating an exemplary configuration of a display device according to a fourth embodiment of the present disclosure;

FIG. 10 is a diagram illustrating an exemplary configuration of a display device according to a fifth embodiment of the present disclosure;

FIG. 11 is a sectional view illustrating an off state of a transmittance control element according to a sixth embodiment of the present disclosure;

FIG. 12 is a sectional view illustrating an on state of the transmittance control element according to the sixth embodiment;

FIG. 13 is a sectional view schematically illustrating a sectional structure of a transmittance control element according to a seventh embodiment of the present disclosure;

FIG. 14 is a sectional view illustrating a non-transmissive state of a transmittance control element according to an eighth embodiment of the present disclosure;

FIG. 15 is a sectional view illustrating a transmissive state of the transmittance control element according to the eighth embodiment; and

FIG. 16 is a sectional view schematically illustrating a sectional structure of a display portion according to a ninth embodiment of the present disclosure.

### DETAILED DESCRIPTION

Exemplary aspects (embodiments) according to the present disclosure are described below in greater detail with reference to the accompanying drawings. The contents described in the embodiments are not intended to limit the present disclosure. Components described below include components easily conceivable by those skilled in the art and components substantially identical therewith. Furthermore, the components described below can be appropriately combined. The disclosure is given by way of example only, and various changes made without departing from the spirit of the disclosure and easily conceivable by those skilled in the art are naturally included in the scope of the disclosure. The drawings may possibly illustrate the width, the thickness, the shape, and the like of each unit more schematically than the actual aspect to simplify the explanation. These elements, however, are given by way of example only and are not intended to limit interpretation of the disclosure. In the specification and the figures, components similar to those previously described with reference to a preceding figure are denoted by like reference numerals, and detailed explanation thereof will be appropriately omitted. In this disclosure, when an element A is described as being “on” another element B, the element A can be directly on the other element B, or there can be one or more elements between the element A and the other element B.

### First Embodiment

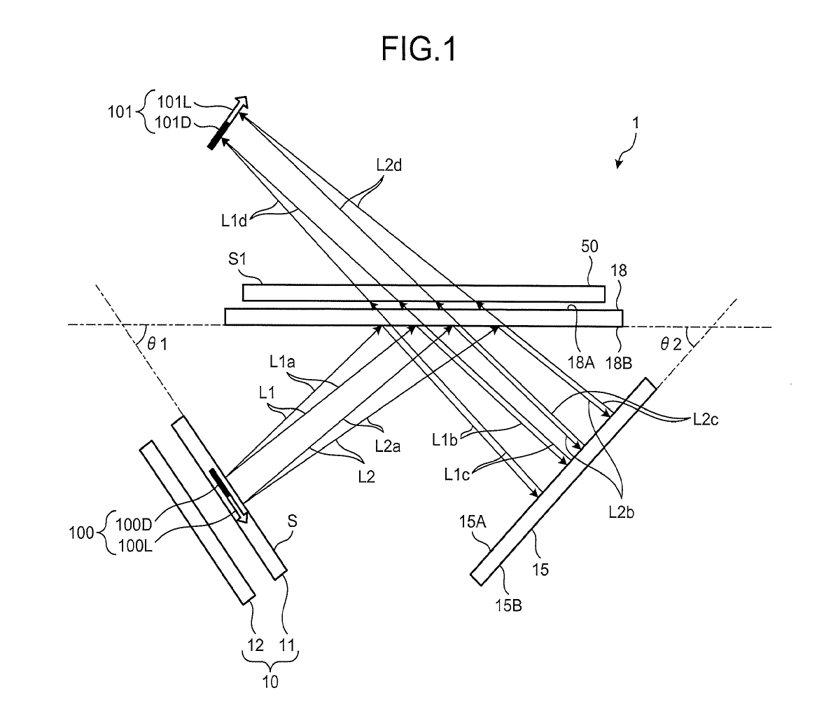

FIG. 1 is a diagram illustrating an exemplary configuration of a display device according to a first embodiment of the present disclosure. As illustrated in FIG. 1, a display device 1 according to the first embodiment includes a display portion 10, an optical element 18, a reflective element 15, and a transmittance control element 50. The display device 1 is an imaging device that produces a formed display image 101 by forming and displaying the image in the air. A display image 100 on the display portion 10 corresponds to a real image of the formed display image 101. The display device 1 can allow viewers to view the formed display image 101 without noticing the display portion 10. The display device 1 is used for, for example, a digital signage or an input interface.

As illustrated in FIG. 1, the display portion 10, the optical element 18, and the reflective element 15 face one another. The optical element 18 is a plate-like member having a first surface 18A and a second surface 18B on the opposite side of the first surface 18A. The transmittance control element 50 faces the first surface 18A of the optical element 18. The second surface 18B of the optical element 18 faces the display portion 10 and the reflective element 15. A display surface S of the display portion 10 is inclined at an angle θ1 to the second surface 18B of the optical element 18. A back surface 15B of the reflective element 15 is inclined at an angle θ2 to the second surface 18B of the optical element 18. A surface S1 of the transmittance control element 50 is substantially parallel to the first surface 18A of the optical element 18. In other words, the surface S1 of the transmittance control element 50 is inclined at the angle θ1 to the display surface S of the display portion 10, and inclined at the angle θ2 to the back surface 15B of the reflective element 15.

The display portion 10 emits display light L1a and display light L2a to display the display image 100. In the description below, display light L1a, display light L1b, display light L1c, and display light L1d are collectively referred to as display light L1 unless otherwise specified. In the same manner, display light L2a, display light L2b, display light L2c, and display light L2d are collectively referred to as display light L2 unless otherwise specified. For easier explanation, the display image 100 illustrated in FIG. 1 is represented by black display 100D and white display 100L. The black display 100D corresponds to a part of the display image 100 having a lower luminance than a certain value. The white display 100L corresponds to a part of the display image 100 having a luminance equal to or higher than the certain value. The display light L1 corresponds to light emitted from the black display 100D of the display image 100. The display light L2 corresponds to light emitted from the white display 100L of the display image 100.

The display light L1a and the display light L2a travel from the display portion 10 to the optical element 18. The optical element 18 transmits or reflects the display light L1 and the display light L2. The display light L1b and the display light L2b specularly reflected at the second surface 18B of the optical element 18 travel toward the reflective element 15.

The reflective element 15 is an optical element that retroreflects the display light L1 and the display light L2. The display light L1b and the display light L2b incident on the reflective element 15 are retroreflected at a reflective surface 15A and travel to the optical element 18. In other words, the display light L1b and the display light L2b incident on the reflective element 15 are reflected back at the reflective surface 15A at a reflection angle equal to the incident angle. The display light L1c and the display light L2c that have been retroreflected at the reflective element 15 pass through the optical element 18 and the transmittance control element 50. The display light L1d and the display light L2d that have passed through the optical element 18 and the transmittance control element 50 form an image in the air close to the first surface 18A of the optical element 18, thereby producing the formed display image 101.

The transmittance control element 50 controls the transmittance of the display light L1 and that of the display light L2. The transmittance control element 50 transmits the display light L1 and the display light L2 at different transmittances in accordance with positions at which the display light L1 and the display light L2 pass through the transmittance control element 50. Specifically, the transmittance control element 50 controls the transmittance of a region through which the display light L1 corresponding to the black display 100D passes to be lower than the transmittance of a region through which the display light L2 corresponding to the white display 100L passes. Accordingly, in the case of the display light L1, the luminance of the display light L1d that has passed through the transmittance control element 50 is made lower than the luminance of the display light L1c entering the transmittance control element 50. In the case of the display light L2, on the other hand, the luminance of the display light L2d that has passed through the transmittance control element 50 is prevented from becoming lower than the luminance of the display light L2c entering the transmittance control element 50. As a result, the luminance of the black display 101D becomes lower than the luminance of the white display 101L in the formed display image 101. In other words, the display device 1 can enhance contrast of the formed display image 101 and improve display quality.

The following describes in detail the components of the display device 1. As illustrated in FIG. 1, the display portion 10 includes a display panel 11 and a lighting device 12. An edge-lit backlight or an array backlight can be employed for the lighting device 12. The edge-lit backlight includes light sources such as light emitting diodes (LEDs) and a light guide. The LEDs are disposed at an edge portion of the light guide. The array backlight includes LEDs that are disposed immediately below a diffuser. The lighting device 12 emits light to the display panel 11.

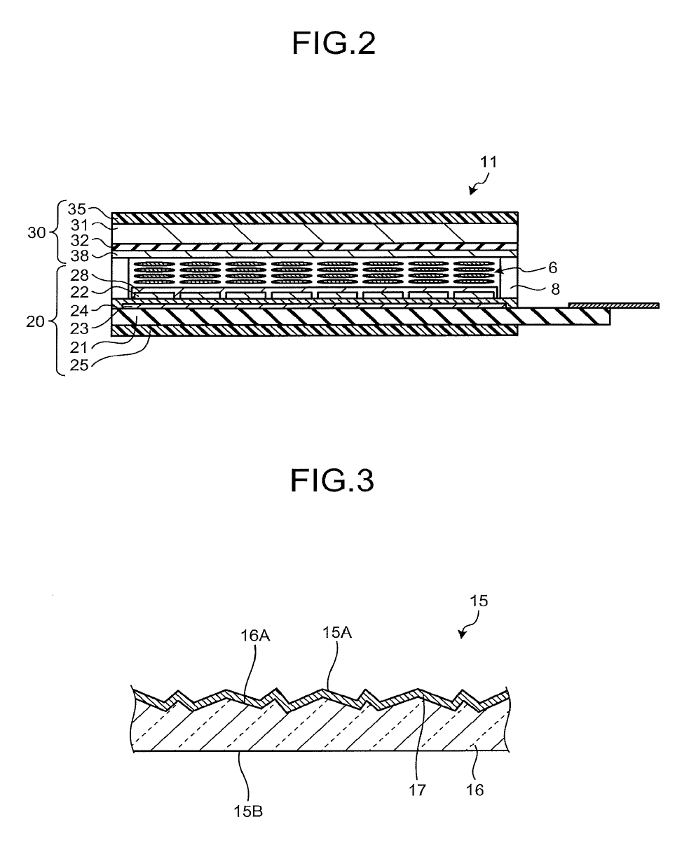

FIG. 2 is a sectional view schematically illustrating a sectional structure of the display panel. The display panel 11 is a transmissive liquid crystal display device. As illustrated in FIG. 2, the display panel 11 includes a pixel substrate 20, a counter substrate 30, and a liquid crystal layer 6 as a display function layer. The counter substrate 30 faces a surface of the pixel substrate 20 in a direction perpendicular to the surface. The liquid crystal layer 6 is disposed between the pixel substrate 20 and the counter substrate 30.

The pixel substrate 20 includes a first substrate 21, pixel electrodes 22, a common electrode 23, an insulating layer 24, a polarizer 25, and an orientation film 28. The first substrate 21 includes circuits, switching elements such as thin film transistors (TFTs), and wiring such as gate lines and signal lines, which are omitted in FIG. 2.

The common electrode 23 is disposed above the first substrate 21. The pixel electrodes 22 are disposed above the common electrode 23 with the insulating layer 24 interposed therebetween. The pixel electrodes 22 are disposed in a layer different from that of the common electrode 23, and overlap with the common electrode 23 in a plan view. The pixel electrodes 22 are arranged in a matrix (row-column configuration) in the plan view. The orientation film 28 is disposed above the pixel electrodes 22. The polarizer 25 is disposed below the first substrate 21. The pixel electrodes 22 and the common electrode 23 are made of, for example, a translucent conductive material such as indium tin oxide (ITO). Although the pixel electrodes 22 are disposed above the common electrode 23 in the first embodiment, the common electrode 23 may be disposed above the pixel electrodes 22.

In the description of the display panel 11, the term “above” as used herein denotes a direction perpendicular to the surface of the first substrate 21 from the first substrate 21 toward a second substrate 31. The term “below” used herein denotes a direction from the second substrate 31 toward the first substrate 21.

The counter substrate 30 includes the second substrate 31, a color filter 32, an orientation film 38, and a polarizer 35. The color filter 32 is formed on one of the surfaces of the second substrate 31. The orientation film 38 is disposed below the color filter 32. The polarizer 35 is disposed on the other surface of the second substrate 31.

The first substrate 21 and the second substrate 31 face each other with a certain interval therebetween. A space formed between the first substrate 21 and the second substrate 31 is sealed with sealing members 8. The liquid crystal layer 6 is disposed in the space defined by the first substrate 21, the second substrate 31, and the sealing members 8. The liquid crystal layer 6 modulates light passing through it in accordance with the state of the electric field. The liquid crystal layer 6 may employ liquid crystal in a horizontal electric field mode such as an in-plane switching (IPS) mode and a fringe field switching (FFS) mode. In the first embodiment, the liquid crystal layer 6 is driven by the horizontal electric field generated between the pixel electrodes 22 and the common electrode 23.

The lighting device 12 illustrated in FIG. 1 includes light sources such as LEDs and projects light rays from the light sources to the first substrate 21. The light rays projected from the lighting device 12 pass through the pixel substrate 20 and are modulated in accordance with the state of the liquid crystals at positions where the light rays pass through the pixel substrate 20. The transmission states of the light rays at the display surface S change in accordance with the positions. The display image 100 is thus displayed on the display surface S.

The display panel 11 illustrated in FIG. 2 is a liquid crystal display device in the horizontal electric field mode, but the present disclosure is not limited thereto. The display panel 11 may be a liquid crystal display device in a vertical electric field mode. In this case, the common electrode 23 is provided to the counter substrate 30. Examples of the vertical electric field mode of the liquid crystal display device include, but are not limited to, a twisted nematic (TN) mode, a vertical alignment (VA) mode, and an electrically controlled birefringence (ECB) mode, in which a vertical electric field is applied to the liquid crystal layer 6.

The optical element 18 illustrated in FIG. 1 can employ a half mirror, for example. The half mirror is made of a glass substrate or a translucent resin substrate with a metal film disposed on one surface thereof. With this configuration, the optical element 18 transmits or reflects the display light L1 and the display light L2. The optical element 18 prevents the display portion 10 and the reflective element 15 from being seen by viewers seeing from the first surface 18A of the optical element 18. The optical element 18 may be any optical element that transmits or reflects the display light L1 and the display light L2. The optical element 18 may be, for example, a reflective polarizing film or a beam splitter such as a dielectric multilayered film.

FIG. 3 is a sectional view schematically illustrating a sectional structure of the reflective element. In the example illustrated in FIG. 3, the reflective element 15 includes a base 16 and a metal film 17. A surface 16A of the base 16 has an uneven surface corresponding to the reflective surface 15A, and the metal film 17 is applied along the uneven surface of the base 16. The metal film 17 thus constitutes the reflective surface 15A. The back surface 15B is an opposite surface of the reflective surface 15A of the reflective element 15, and is a plane surface. As illustrated in FIG. 1, the reflective surface 15A of the reflective element 15 faces inward in the display device 1. That is, the reflective surface 15A of the reflective element 15 faces the second surface 18B of the optical element 18. The back surface 15B of the reflective element 15 faces away from the optical element 18.

Most of the display light L1 and the display light L2 traveling from the optical element 18 to the reflective surface 15A are reflected back toward the optical element 18 at angles equal to the incident angles. The transmittance of the display light L1 and the display light L2 incident on the reflective element 15 at the reflective surface 15A is substantially zero. In other words, the display light L1 and the display light L2 incident on the reflective element 15 hardly reaches the back surface 15B of the reflective element 15. With this exemplary configuration, the display device 1 can prevent ghosts that are caused by optical reflection at the back surface 15B.

The metal film 17 may be subjected to a surface treatment to prevent corrosion or damage. The metal film 17 may be top-coated with an inorganic material such as silicon nitride (SiN) or an organic material such as a translucent resin. In this case, the reflective element 15 may have a plane portion on the reflective surface 15A.

If the base 16 is made of an optically reflective material, a surface 16A of the base 16 may serve as the reflective surface 15A. In this case, a process of forming an optically reflective layer such as the metal film 17 can be eliminated from the manufacturing procedure.

If the surface 16A of the base 16 is adjacent to a material having a different refractive index (e.g., air layer), the reflective element 15 do not necessarily have the metal film 17. In this case, light incident on the reflective element 15 is retroreflected at the surface 16A of the base 16 by interfacial reflection. That is, the surface 16A of the base 16 corresponds to the reflective surface 15A.

The reflective element 15 may be provided with the base 16 inside the display device 1 and with the metal film 17 outside the display device 1. In this case, the reflective element 15 has a plane surface (back surface 15B) inside the display device 1 and an uneven surface corresponding to the reflective surface 15A outside the display device 1.

As described above, the plane including the second surface 18B of the optical element 18 is disposed at the angle θ1 to the plane including the display surface S of the display portion 10. The angle θ1 is not limited to a specific value and may be any values at which the display light L1 and the display light L2 from the display portion 10 can be incident on the second surface 18B of the optical element 18. For example, the angle θ1 is set to an acute angle from larger than zero degree to smaller than 90 degrees. If the angle θ1 is equal to or larger than 45 degrees and smaller than 90 degrees, the display light L1 and the display light L2 from the display portion 10 can be incident on the optical element 18 efficiently.

The plane including the back surface 15B of the reflective element 15 is disposed at the angle θ2 to the plane including the second surface 18B of the optical element 18. The angle θ2 is not limited to a specific value and may be any values at which the display light L1 and the display light L2 reflected at the optical element 18 can be incident on the reflective surface 15A. For example, the angle θ2 is preferably set in the range from 45 degrees to 135 degrees inclusive. If the angle θ2 is in this range, the reflective element 15 can retroreflect the display light L1 and the display light L2 at the reflective surface 15A efficiently. The angle θ2 is more preferably equal to or larger than 45 degrees and smaller than 90 degrees. At least a portion of the reflective element 15 may be curved. In this case, the angle θ2 varies depending on the in-plane position in the reflective element 15.

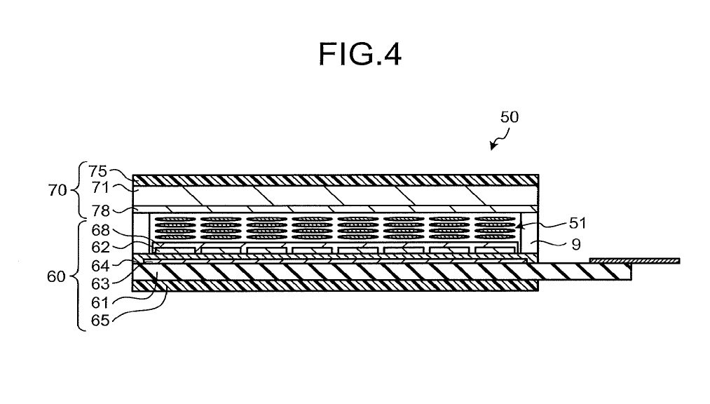

FIG. 4 is a sectional view schematically illustrating a sectional structure of the transmittance control element. In the first embodiment, the transmittance control element 50 is a transmissive liquid crystal element and has a configuration similar to the display panel 11 (see FIG. 2). As illustrated in FIG. 4, the transmittance control element 50 includes a lower substrate 60, an upper substrate 70, and a liquid crystal layer 51 as a transmittance control layer. The upper substrate 70 faces a surface of the lower substrate 60 in a direction perpendicular to the surface. The liquid crystal layer 51 is disposed between the lower substrate 60 and the upper substrate 70.

The lower substrate 60 includes a first substrate 61, first electrodes 62, a second electrode 63, an insulating layer 64, a polarizer 65, and an orientation film 68. The first substrate 61 includes circuits, switching elements such as TFTs, and wiring such as gate lines and signal lines, which are omitted in FIG. 4.

The second electrode 63 is disposed above the first substrate 61. The first electrodes 62 are disposed above the second electrode 63 with the insulating layer 64 interposed therebetween, and overlap with the second electrode 63 in a plan view. The first electrodes 62 are arranged in a matrix (row-column configuration) in the plan view. The first electrodes 62 correspond to the pixel electrodes 22 illustrated in FIG. 2, and are arranged at the same pitch as that of the pixel electrodes 22. However, the first electrodes 62 are not limited to this configuration. The first electrodes 62 may have a larger surface area than that of the pixel electrodes 22 and may be arranged at a greater pitch than that of the pixel electrodes 22. The orientation film 68 is disposed above the first electrodes 62. The polarizer 65 is disposed below the first substrate 61. The first electrodes 62 and the second electrode 63 are made of, for example, a translucent conductive material such as ITO. The second electrode 63 may be disposed above the first electrodes 62.

In the description of the transmittance control element 50, the term “above” as used herein denotes a direction perpendicular to the surface of the first substrate 61 from the first substrate 61 toward a second substrate 71. The term “below” used herein denotes a direction from the second substrate 71 to the first substrate 61.

The upper substrate 70 includes the second substrate 71, an orientation film 78, and a polarizer 75. The orientation film 78 is disposed on one of the surfaces of the second substrate 71. The polarizer 75 is disposed on the other surface of the second substrate 71. Unlike the display panel 11 illustrated in FIG. 2, the transmittance control element 50 includes no color filter 32, and the orientation film 78 is directly disposed on the second substrate 71.

The first substrate 61 and the second substrate 71 face each other with a certain interval therebetween. A space formed between the first substrate 61 and the second substrate 71 is sealed with sealing members 9. The liquid crystal layer 51 is disposed in the space defined by the first substrate 61, the second substrate 71, and the sealing members 9. The liquid crystal layer 51 modulates light passing through it in accordance with the state of the electric field. The liquid crystal layer 51 may employ, for example, liquid crystal in the horizontal electric field mode such as the IPS mode and the FFS mode. In the first embodiment, the liquid crystal layer 51 is driven by the horizontal electric field generated between the first electrodes 62 and the second electrode 63.

The display light L1c and the display light L2c retroreflected at the reflective element 15 illustrated in FIG. 1 pass through the optical element 18 and enter the first substrate 61. The display light L1c and the display light L2c pass through the lower substrate 60 and are modulated in accordance with the state of the liquid crystals at positions where the display light L1c and the display light L2c pass through the lower substrate 60. The transmission states of the display light L1c and the display light L2c change in accordance with the positions. For example, the liquid crystal layer 51 is driven so as to reduce the transmittance of the display light L1 corresponding to the black display 100D at a position where the display light L1c passes through the lower substrate 60. On the other hand, the liquid crystal layer 51 is driven so as to prevent reduction in the transmittance of the display light L2c corresponding to the white display 100L at a position where the display light L2c passes through the lower substrate 60.

With this configuration, the luminance of the display light L1d emitted from the transmittance control element 50 is made lower than the luminance of the display light L1c entering the transmittance control element 50. The luminance of the display light L2d emitted from the transmittance control element 50 is prevented from becoming lower than the luminance of the display light L2c entering the transmittance control element 50. With this configuration, the display device 1 according to the first embodiment enhances contrast of the formed display image 101 produced in the air. The display device 1 can prevent degradation of display quality of an image formed by the display light L1 and the display light L2 even after having been reflected a plurality of times.

In the first embodiment, the transmittance control element 50 faces the first surface 18A of the optical element 18. That is, no optical member such as the optical element 18 or the reflective element 15 is disposed between the transmittance control element 50 and the formed display image 101 produced in the air. The display light L1d and the display light L2d that have passed through the transmittance control element 50 form an image without passing through any optical members, thereby preventing reflection or diffusion of the display light L1d and the display light L2d. With this configuration, the display device 1 can enhance contrast of the formed display image 101.

In a configuration in which no transmittance control element 50 is provided, when ambient light other than the display light L1 and the display light L2 is reflected at the optical element 18 and illuminates the formed display image 101, the contrast of the formed display image 101 may be lowered. In the first embodiment, the transmittance control element 50 faces the first surface 18A of the optical element 18, and thus the ambient light is reflected at the optical element 18 and passes through the transmittance control element 50 twice. Consequently, the transmittance control element 50 reduces the luminance of the ambient light at a position corresponding to the black display 101D and prevents reduction in the luminance of the ambient light at a position corresponding to the white display 101L. With this configuration, the display device 1 can prevent lower contrast of the formed display image 101 caused by the ambient light.

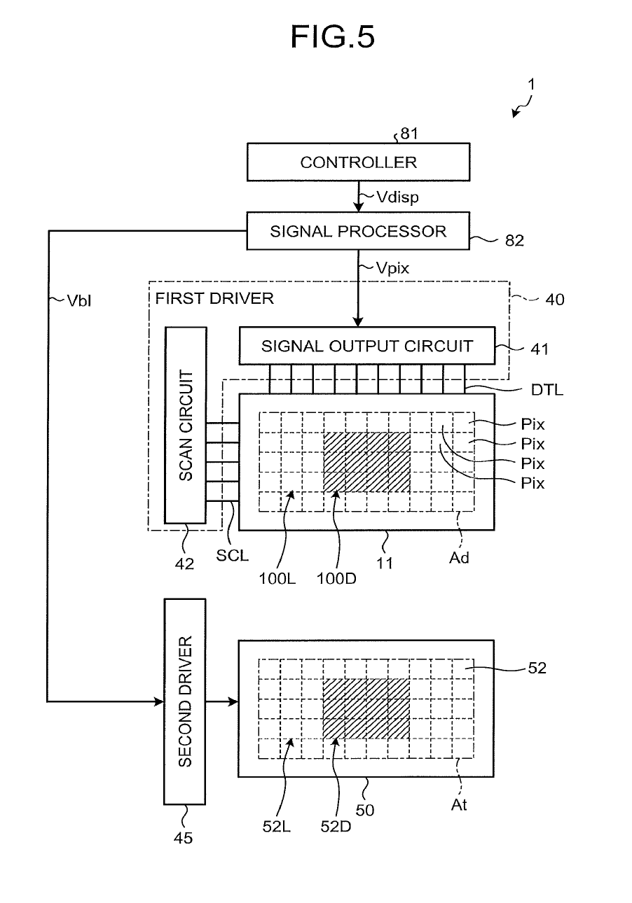

The following describes an example method of driving the display device 1 according to the first embodiment. FIG. 5 is a block diagram illustrating an exemplary configuration of the display device. As illustrated in FIG. 5, the display device 1 includes: the display panel 11 and the transmittance control element 50, which are described above, a controller 81, a signal processor 82, a first driver 40, and a second driver 45.

The controller 81 is a circuit for controlling display operations of the display panel 11 and operations of the transmittance control element 50. The signal processor 82 is an arithmetic processor for controlling the operations of the display panel 11 and the transmittance control element 50 in accordance with a control signal Vdisp from the controller 81. The controller 81 and the signal processor 82 may be implemented by a single semiconductor integrated circuit (IC) or may be implemented by different semiconductor ICs.

The first driver 40 is a circuit for controlling the drive of the display panel 11. The first driver 40 includes a signal output circuit 41 and a scan circuit 42. The signal output circuit 41 is electrically coupled to the display panel 11 via signal lines DTL. The scan circuit 42 is electrically coupled to the display panel 11 via scan lines SCL. The scan circuit 42 of the first driver 40 controls on and off of switching elements (e.g., TFTs) for controlling the display operations of pixels Pix. This switching control selects target pixels Pix to be displayed on the display panel 11. The signal output circuit 41 of the first driver 40 retains video signals Vpix and sequentially outputs the video signals Vpix to the target pixels Pix.

The pixels Pix are arranged in a matrix (row-column configuration) in a display region Ad. Each pixel Pix may include a set of a sub-pixel for displaying red (R), a sub-pixel for displaying green (G), and a sub-pixel for displaying blue (B). Each pixel Pix may include sub-pixels of four or more colors.

The second driver 45 is a circuit for controlling the drive of the transmittance control element 50. The second driver 45 includes a signal output circuit and a scan circuit, which are not illustrated, in the same manner as the first driver 40. The second driver 45 controls the operations (transmittance) of unit regions 52 in accordance with control signals Vbl supplied from the signal processor 82.

As illustrated in FIG. 5, the unit regions 52 are arranged in a matrix (row-column configuration) in a translucent region At of the transmittance control element 50. The unit regions 52 each correspond to a first electrode 62 illustrated in FIG. 4 and are arranged at the same pitch as the first electrodes 62. In the example illustrated in FIG. 5, for easier explanation, the number and arrangement pitch of unit regions 52 are the same as those of the pixels Pix.

The signal processor 82 generates the video signals Vpix for the pixels Pix and supplies them to the first driver 40, and computes luminance of each pixel Pix. If the luminance of a pixel Pix is lower than a certain value, the signal processor 82 determines that display by the pixel Pix is the black display 100D. If the luminance of a pixel Pix is equal to or higher than the certain value, the signal processor 82 determines that display by the pixel Pix is the white display 100L. In FIG. 5, pixels Pix performing the black display 100D are hatched.

The signal processor 82 supplies control signals Vbl corresponding to the luminance of the respective pixels Pix to the second driver 45. The second driver 45 drives the liquid crystal layer 51 (see FIG. 4) such that unit regions 52D corresponding to the pixels Pix performing the black display 100D transmit the display light L1 at a lower transmittance. The second driver 45 drives the liquid crystal layer 51 (see FIG. 4) such that unit regions 52L corresponding to the pixels Pix performing the white display 100L transmit the display light L2 without lowering the transmittance of the display light L2. In FIG. 5, the unit regions 52D corresponding to the black display 100D are hatched.

The controller 81 and the signal processor 82 control the transmittance of the transmittance control element 50 for each unit region 52. With this configuration, the luminance of the display light L1 corresponding to the black display 100D transmitting the transmittance control element 50 is made lower, while the luminance of the display light L2 corresponding to the white display 100L is prevented from being lowered. As illustrated in FIG. 5, the transmittance control element 50 controls the transmittance of each unit region 52 corresponding to a pixel Pix. Accordingly, the display device 1 can control contrast of the formed display image 101 produced in the air at high resolution.

The controller 81 and the signal processor 82 drive the transmittance control element 50 in synchronization with the display panel 11. Depending on the resolution or frame rates of the display image 100 and the formed display image 101, the controller 81 and the signal processor 82 may drive the transmittance control element 50 without being synchronized with the display panel 11.

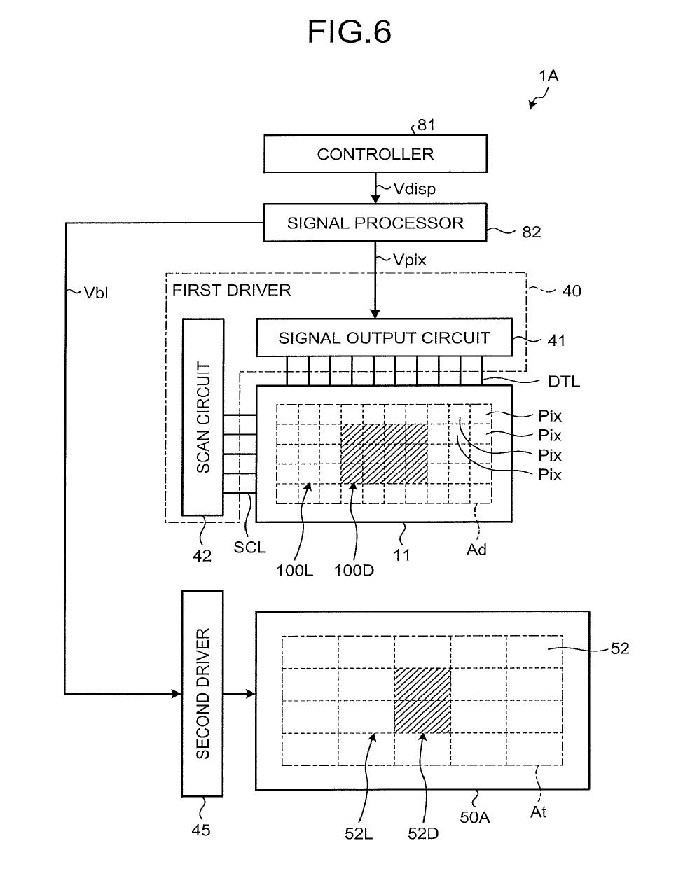

FIG. 6 is a block diagram illustrating an exemplary configuration of a display device according to a modification of the first embodiment. In a display device 1A according to the modification, the translucent region At of a transmittance control element 50A has a larger area than that of the display region Ad of the display panel 11. Each unit region 52 of the transmittance control element 50A has a larger area than that of each unit region 52 of the transmittance control element 50 illustrated in FIG. 5. In the present modification, the first electrodes 62 (see FIG. 4) correspond to the unit regions 52 on a one-on-one basis. Alternatively, a plurality of first electrodes 62 may be provided for each unit region 52.

In some cases, the formed display image 101 (see FIG. 1) produced in the air may not require high resolution in comparison with the resolution of the display image 100 on the display panel 11. In such a case, the translucent region At may be divided into a smaller number of unit regions 52 as described in the present modification. In the present modification, the unit regions 52 are obtained by dividing the translucent region At into five in the row direction and into four in the column direction. FIG. 6 is for illustrative purposes only, and the translucent region At may be divided into any number as appropriate. For example, the display device 1A may have unit regions 52 obtained by dividing the translucent region At into the same number in the row direction and in the column direction.

The number of unit regions 52 is smaller than that of the pixels Pix of the display panel 11. The unit regions 52 are arranged at a greater pitch than the pitch at which the pixels Pix are arranged. That is, each unit region 52 corresponds to a plurality of pixels Pix in the present modification. Specifically, the display light L1 and the display light L2 emitted from the pixels Pix pass through one unit region 52. The signal processor 82 computes, for example, the luminance of the pixels Pix corresponding to one unit region 52 and computes a mean value of the luminance for the unit region 52. The signal processor 82 supplies control signals Vbl corresponding to the luminance of the respective unit regions 52 to the second driver 45.

The second driver 45 drives the liquid crystal layer 51 (see FIG. 4) such that unit regions 52D corresponding to the pixels Pix performing the black display 100D transmit the display light L1 at a lower transmittance. The second driver 45 drives the liquid crystal layer 51 (see FIG. 4) such that unit regions 52L corresponding to the pixels Pix performing the white display 100L transmit the display light L2 without lowering the transmittance of the display light L2.

In the present modification, one unit region 52 corresponds to the pixels Pix, thereby allowing the transmittance control element 50A a greater degree of freedom in display performance of the display panel 11 such as resolution. Even when including another display panel 11 at different resolution, the display device 1A can properly control the contrast of the formed display image 101 produced in the air by causing the transmittance control element 50A to control the transmittance of each unit region 52.

### Second Embodiment

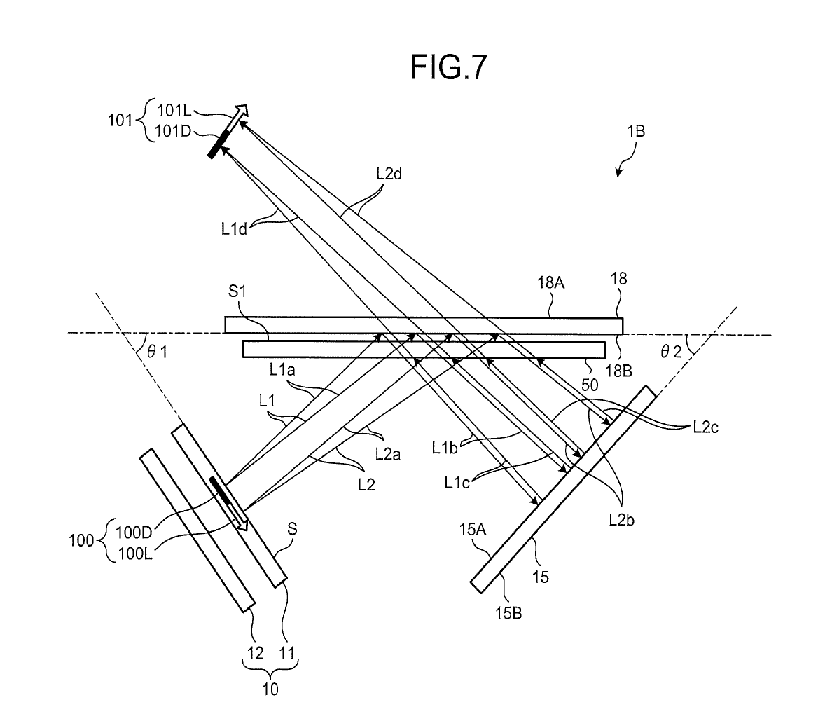

FIG. 7 is a diagram illustrating an exemplary configuration of a display device according to a second embodiment of the present disclosure. In a display device 1B according to the second embodiment, the transmittance control element 50 faces the second surface 18B of the optical element 18. That is, the transmittance control element 50 is disposed between the optical element 18 and the display portion 10 and between the optical element 18 and the reflective element 15. Also in the second embodiment, the surface S1 of the transmittance control element 50 is substantially parallel to the first surface 18A of the optical element 18. That is, the surface S1 of the transmittance control element 50 is inclined at the angle θ1 to the display surface S of the display panel 11, and inclined at the angle θ2 to the back surface 15B of the reflective element 15.

This transmittance control element 50 has the same configuration as that of the transmittance control element 50 illustrated in FIG. 4. The transmittance control element 50 is disposed such that the second substrate 71 (see FIG. 4) faces the optical element 18 and the first substrate 61 (see FIG. 4) faces the display portion 10 and the reflective element 15.

In the second embodiment, the display light L1a and the display light L2a emitted from the display portion 10 pass through the transmittance control element 50, and are reflected specularly at the second surface 18B of the optical element 18. The display light L1b and the display light L2b specularly reflected at the optical element 18 then pass through the transmittance control element 50, and are retroreflected at the reflective element 15. The display light L1c and the display light L2c that have been retroreflected at the reflective element 15 pass through the transmittance control element 50 and the optical element 18. The display light L1d and the display light L2d that have passed through the optical element 18 form an image in the air close to the first surface 18A of the optical element 18, thereby producing the formed display image 101.

As described above, the display light L1 and the display light L2 pass through the transmittance control element 50 three times and form an image in the air. In the case of the display light L1 corresponding to the black display 101D, the luminance of the display light L1d that has passed through the transmittance control element 50 is made lower than the luminance of the display light L1a emitted from the display panel 11. In the case of the display light L2 corresponding to the white display 101L, on the other hand, the luminance of the display light L2d that has passed through the transmittance control element 50 is prevented from being lowered. With this configuration, the display device 1B can enhance contrast of the formed display image 101.

### Third Embodiment

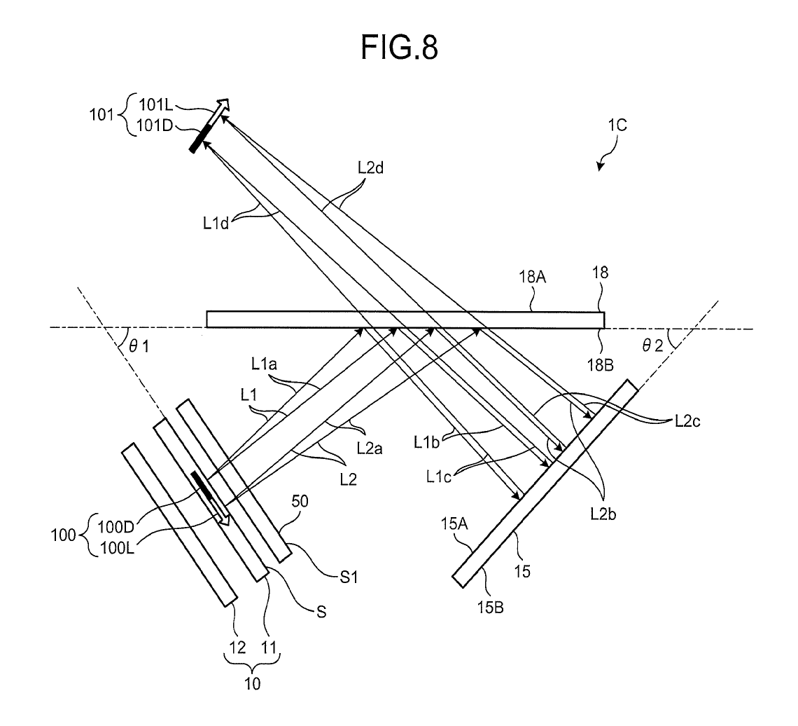

FIG. 8 is a diagram illustrating an exemplary configuration of a display device according to a third embodiment of the present disclosure. In a display device 1C according to the third embodiment, the transmittance control element 50 faces the display surface S of the display panel 11. That is, the transmittance control element 50 is disposed between the display panel 11 and the optical element 18 and between the display panel 11 and the reflective element 15. In the third embodiment, the surface S1 of the transmittance control element 50 is substantially parallel to the display surface S of the display panel 11. That is, the surface S1 of the transmittance control element 50 is inclined at the angle θ1 to the second surface 18B of the optical element 18.

In the third embodiment, the display light L1a and the display light L2a emitted from the display portion 10 pass through the transmittance control element 50 and are reflected specularly at the second surface 18B of the optical element 18. The display light L1b and the display light L2b specularly reflected at the optical element 18 are then retroreflected at the reflective element 15. The display light L1c and the display light L2c retroreflected at the reflective element 15 then pass through the optical element 18. The display light L1d and the display light L2d that have passed through the optical element 18 form an image in the air close to the first surface 18A of the optical element 18, thereby producing the formed display image 101.

In the third embodiment, disposing the transmittance control element 50 so as to face the display surface S facilitates control of the transmittance for each pixel Pix by the transmittance control element 50. In other words, the contrast of the display light L1a and the display light L2a can be controlled at high resolution. In the third embodiment, the transmittance control element 50 may be stacked on the display panel 11 so that they are integrated with each other. In this case, at least one of the polarizers 25 and 35 (see FIG. 2) of the display panel 11 and the polarizers 65 and 75 (see FIG. 4) of the transmittance control element 50 can be eliminated. With this configuration, the display device 1C can prevent transmittances of the display light L1 and the display light L2 from being lowered and increase overall luminance of the formed display image 101.

### Fourth Embodiment

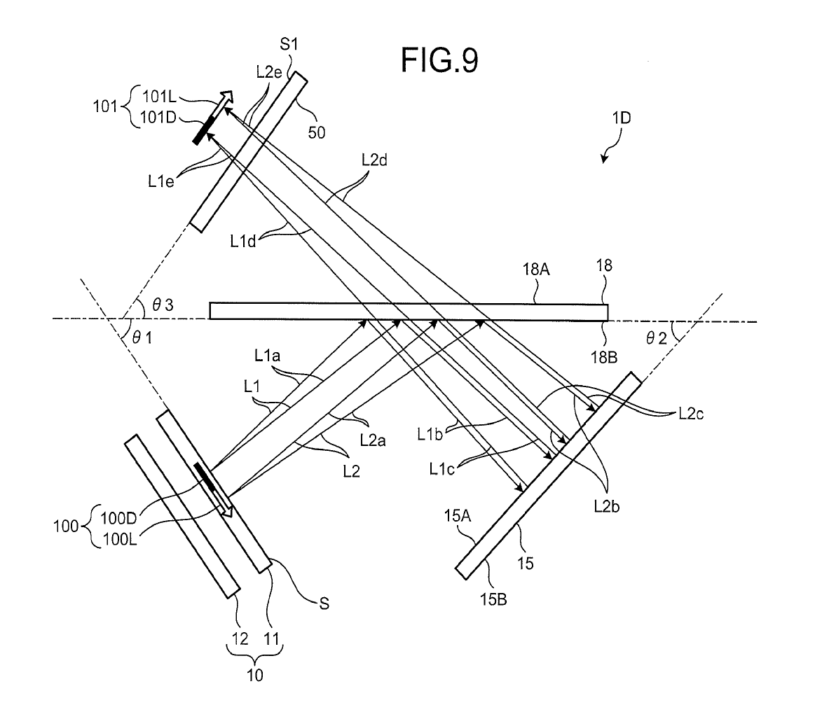

FIG. 9 is a diagram illustrating an exemplary configuration of a display device according to a fourth embodiment of the present disclosure. In a display device 1D according to the fourth embodiment, the transmittance control element 50 is disposed close to the formed display image 101. The transmittance control element 50 is disposed between the first surface 18A of the optical element 18 and the formed display image 101. The plane including the surface S1 of the transmittance control element 50 is disposed at an angle θ3 to the plane including the second surface 18B of the optical element 18. In other words, the transmittance control element 50 is inclined with respect to the optical element 18. The angle θ3 at which the transmittance control element 50 is inclined is preferably equal to the angle θ1 at which the display panel 11 is inclined.

In the fourth embodiment, the display light L1a and the display light L2a emitted from the display portion 10 are reflected specularly at the second surface 18B of the optical element 18. The display light L1b and the display light L2b specularly reflected at the optical element 18 are then retroreflected at the reflective element 15. The display light L1c and the display light L2c retroreflected at the reflective element 15 then pass through the optical element 18. The display light L1d and the display light L2d that have passed through the optical element 18 then pass through the transmittance control element 50. Display light L1e and L2e that have passed through the transmittance control element 50 form an image near the transmittance control element 50, thereby producing the formed display image 101.

In the fourth embodiment, disposing the transmittance control element 50 close to the formed display image 101 facilitates control of the transmittance for each pixel Pix by the transmittance control element 50. In other words, even if the display light L1 and the display light L2 are repeatedly reflected and diffused at the display panel 11, the optical element 18, and the reflective element 15, the display device 1D can enhance display quality of the formed display image 101 by controlling the contrast of the display light L1e and L2e at high resolution.

In the fourth embodiment, the display portion 10 and the reflective element 15 are accommodated in a housing (not illustrated) and the optical element 18 is disposed at an upper portion of the housing. The method of installing the transmittance control element 50 may be, but is not limited to, fixing it to the housing or the like, or installing it through the use of a wall or a ceiling, for example. In the fourth embodiment, the transmittance control element 50 is preferably a transparent liquid crystal element. With this configuration, the viewers can see the formed display image 101 through the transmittance control element 50 without noticing the transmittance control element 50.

### Fifth Embodiment

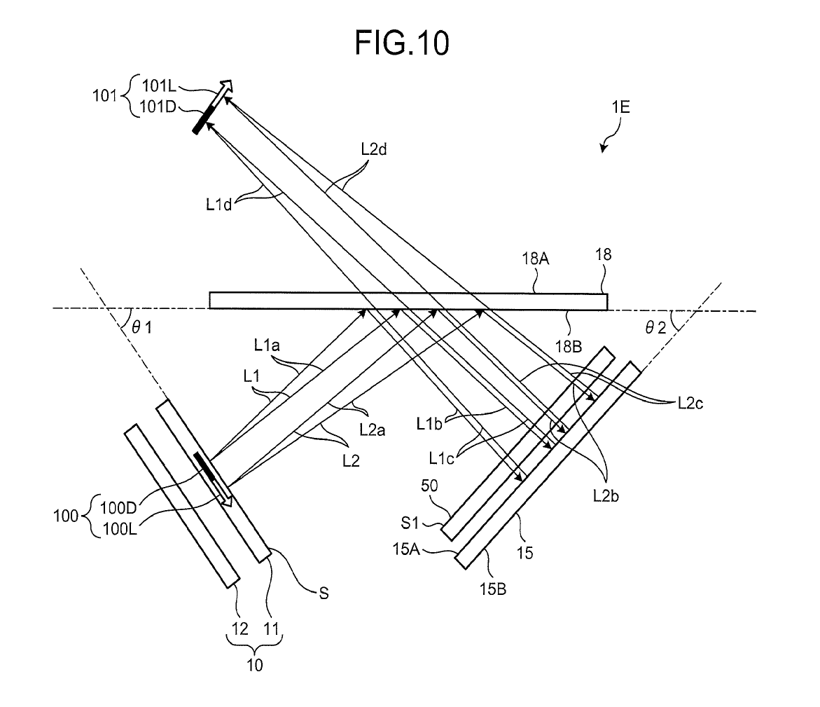

FIG. 10 is a diagram illustrating an exemplary configuration of a display device according to a fifth embodiment of the present disclosure. In a display device 1E according to the fifth embodiment, the transmittance control element 50 faces the reflective element 15. That is, the transmittance control element 50 is disposed between the reflective element 15 and the optical element 18 and between the display panel 11 and the reflective element 15.

The transmittance control element 50 is substantially parallel to the back surface 15B of the reflective element 15. In other words, the transmittance control element 50 is inclined at the angle θ2 to the second surface 18B of the optical element 18. The transmittance control element 50 is apart from the reflective surface 15A of the reflective element 15 so as not to interfere with the function of the reflective surface 15A.

In the fifth embodiment, the display light L1a and the display light L2a emitted from the display portion 10 are reflected specularly at the second surface 18B of the optical element 18. The display light L1b and the display light L2b specularly reflected at the optical element 18 then pass through the transmittance control element 50, and are retroreflected at the reflective element 15. The display light L1c and the display light L2c that have been retroreflected at the reflective element 15 pass through the transmittance control element 50 and the optical element 18. The display light L1d and the display light L2d that have passed through the optical element 18 form an image in the air, thereby producing the formed display image 101.

As described above, the display light L1 and the display light L2 pass through the transmittance control element 50 twice and form an image in the air. In the case of the display light L1 corresponding to the black display 101D, the luminance of the display light L1c that has passed through the transmittance control element 50 is made lower than the display light L1a emitted from the display panel 11. In the case of the display light L2 corresponding to the white display 101L, on the other hand, the luminance of the display light L2c that has passed through the transmittance control element 50 is prevented from being lowered. With this configuration, the display device 1E can enhance contrast of the formed display image 101.

In the fifth embodiment, the transmittance control element 50 faces the reflective element 15. Accordingly, when ambient light, which is different from the display light L1 and the display light L2, enters the inside of the display device 1E, for example, the ambient light is also reflected at the reflective element 15 and passes through the transmittance control element 50 twice. Consequently, the luminance of the ambient light is lowered at a position corresponding to the black display 101D, and the luminance of the ambient light is prevented from being lowered at a position corresponding to the white display 101L. With this configuration, the display device 1E can prevent lower contrast of the formed display image 101 caused by the ambient light.

### Sixth Embodiment

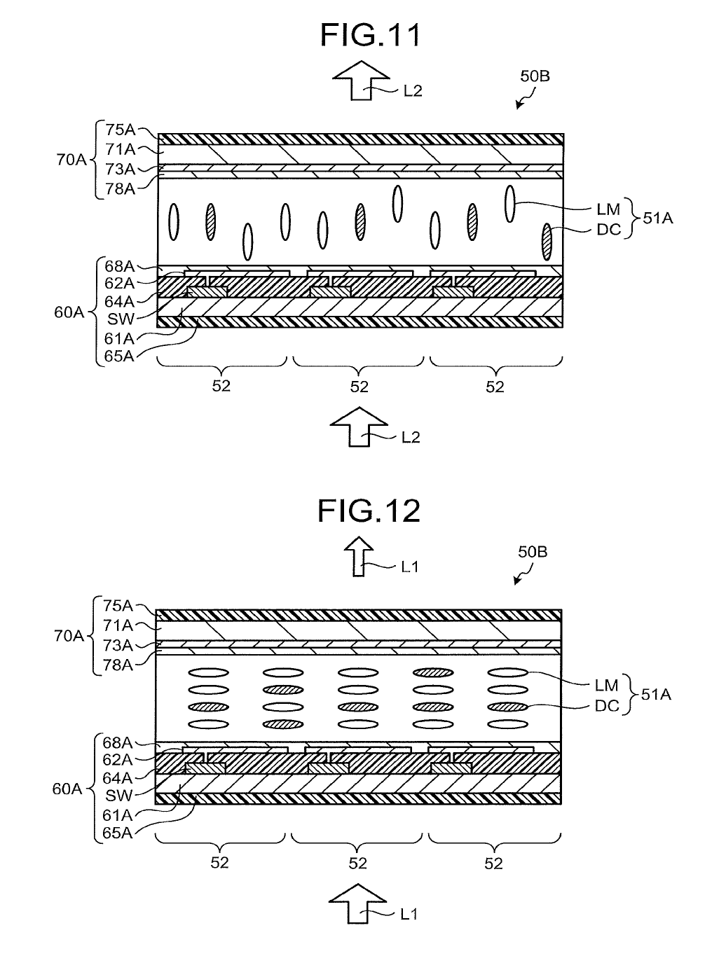

FIG. 11 is a sectional view illustrating an off state of a transmittance control element according to a sixth embodiment of the present disclosure. FIG. 12 is a sectional view illustrating an on state of the transmittance control element according to the sixth embodiment. This transmittance control element 50B according to the sixth embodiment is a guest-host liquid crystal element. As illustrated in FIGS. 11 and 12, the transmittance control element 50B includes a lower substrate 60A, an upper substrate 70A, and a liquid crystal layer 51A as a transmittance control layer.

The lower substrate 60A includes a first substrate 61A, switching elements SW such as TFTs, an insulating layer 64A, first electrodes 62A, a polarizer 65A, and an orientation film 68A. The first electrodes 62A are disposed above the first substrate 61A with the insulating layer 64A interposed therebetween. The first electrodes 62A are arranged in a matrix (row-column configuration) in a plan view. The first electrodes 62A are electrically coupled to the respective switching elements SW through respective contact holes formed in the insulating layer 64A. The orientation film 68A is disposed above the first electrodes 62A. The polarizer 65A is disposed below the first substrate 61A.

The upper substrate 70A includes a second substrate 71A, a second electrode 73A, an orientation film 78A, and a polarizer 75A. The second electrode 73A is disposed on one of the surfaces of the second substrate 71A. The orientation film 78A is disposed below the second electrode 73A. The polarizer 75A is disposed on the other surface of the second substrate 71A. Unlike the display panel 11 illustrated in FIG. 2, the transmittance control element 50B includes no color filter 32.

The liquid crystal layer 51A is disposed between the first substrate 61A and the second substrate 71A. That is, the liquid crystal layer 51A is disposed between the first electrodes 62A and the second electrode 73A. In the sixth embodiment, the liquid crystal layer 51A is driven by the vertical electric field generated between the first electrodes 62A and the second electrode 73A.

The liquid crystal layer 51A is what is called a guest-host liquid crystal layer including liquid crystal molecules LM and dichroic dyes DC. The liquid crystal molecules LM (host liquid crystal) are liquid crystal molecules with negative dielectric anisotropy. The dichroic dyes DC (guest dyes) are, for example, black dyes. The dichroic dyes DC are oriented along the liquid crystal molecules LM. The orientations of the liquid crystal molecules LM are changed by the electric field generated between the first electrodes 62A and the second electrode 73A, and the orientations of the dichroic dyes DC are changed accordingly.

As illustrated in FIG. 11, the liquid crystal molecules LM and the dichroic dyes DC are oriented substantially perpendicular to the first substrate 61A in a state in which no electric field is generated between the first electrodes 62A and the second electrode 73A (off state). In the off state, the display light L2 passes through the liquid crystal layer 51A without being absorbed by the dichroic dyes DC. With this configuration, the transmittance control element 50B prevents reduction in the luminance of the display light L2 that has passed through the transmittance control element 50B.

As illustrated in FIG. 12, the liquid crystal molecules LM and the dichroic dyes DC are oriented substantially parallel to the first substrate 61A in a state in which vertical electric field is generated between the first electrodes 62A and the second electrode 73A (on state). In the on state, the display light L1 is absorbed by the dichroic dyes DC. With this configuration, the transmittance control element 50B reduces the transmittance of the display light L1 passing through the liquid crystal layer 51A and reduces the luminance of the display light L1 that has passed through the transmittance control element 50B.

The transmittance control element 50B according to the sixth embodiment includes black dyes as the dichroic dyes DC. Using the black dyes can further reduce the transmittance of the liquid crystal layer 51A in the on state. With this configuration, the transmittance control element 50B can enhance contrast of the formed display image 101. The transmittance control element 50B according to the sixth embodiment can be used for the display devices 1 and 1A to 1E according to the first to the fifth embodiments described above.

The direction of the polarization axis of the polarizers 65A and 75A preferably matches the direction of the polarization axis of the polarizer 35 (see FIG. 2) of the display panel 11. The transmittance control element 50B may eliminate at least one of the polarizers 65A and 75A. The transmittance control element 50B can control the on state and the off state of the liquid crystal layer 51A for each unit region 52.

### Seventh Embodiment

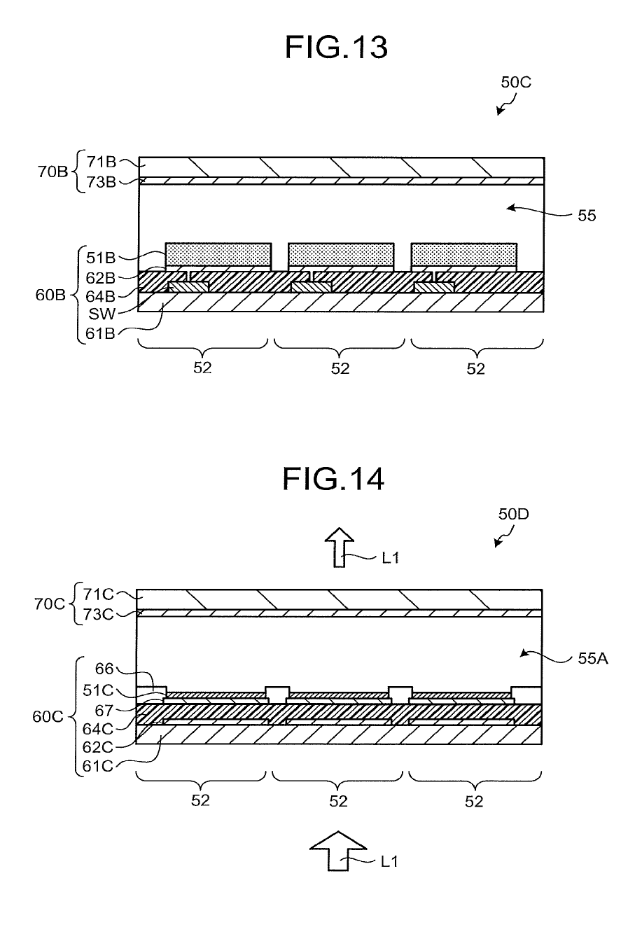

FIG. 13 is a sectional view schematically illustrating a sectional structure of a transmittance control element according to a seventh embodiment of the present disclosure. This transmittance control element 50C according to the seventh embodiment is an electrochromic element. As illustrated in FIG. 13, the transmittance control element 50C includes a lower substrate 60B, an upper substrate 70B, and an electrolyte layer 55. The lower substrate 60B includes an electrochromic layer 51B as a transmittance control layer.

The lower substrate 60B includes a first substrate 61B, switching elements SW such as TFTs, an insulating layer 64B, first electrodes 62B, and the electrochromic layer 51B. The first electrodes 62B are disposed above the first substrate 61B with the insulating layer 64B interposed therebetween. The first electrodes 62B are arranged in a matrix (row-column configuration) in a plan view. The first electrodes 62B are electrically coupled to the respective switching elements SW through respective contact holes formed in the insulating layer 64B. The electrochromic layer 51B is disposed on the first electrodes 62B.

The upper substrate 70B includes a second substrate 71B and a second electrode 73B. The second electrode 73B is disposed below the second substrate 71B. The second electrode 73B is disposed above the electrochromic layer 51B with the electrolyte layer 55 interposed therebetween. The electrolyte layer 55 is provided to increase adhesion between the second electrode 73B and the electrochromic layer 51B.

The electrochromic layer 51B changes the spectrum of light passing therethrough in accordance with a voltage applied between the first electrodes 62B and the second electrode 73B. For example, the electrochromic layer 51B may be made of a conjugated polymer selected from a group consisting of polyparaphenylenes, polythiophenes, polyphenylene vinylenes, polypyrroles, polyanilines, arylamine-substituted poly(arylene vinylenes), and polyfluorene polymers.

The transmittance control element 50C according to the seventh embodiment can change the transmittance in accordance with a voltage applied to the electrochromic layer 51B, thereby allowing extension of a controllable range of the transmittance. That is, the transmittance of the electrochromic layer 51B can be increased at a unit region 52 through which the display light L2 passes, and the transmittance of the electrochromic layer 51B can be reduced at a unit region 52 through which the display light L1 passes. With this configuration, the transmittance control element 50C can enhance contrast of the formed display image 101. The transmittance control element 50C according to the seventh embodiment can be used for the display devices 1 and 1A to 1E according to the first to the fifth embodiments described above.

### Eighth Embodiment

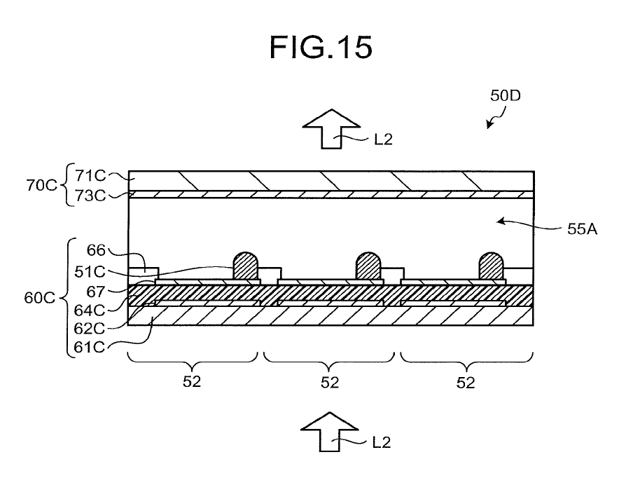

FIG. 14 is a sectional view illustrating a non-transmissive state of a transmittance control element according to an eighth embodiment of the present disclosure. FIG. 15 is a sectional view illustrating a transmissive state of the transmittance control element according to the eighth embodiment. This transmittance control element 50D according to the eighth embodiment is an electrowetting element. As illustrated in FIGS. 14 and 15, the transmittance control element 50D includes a lower substrate 60C, an upper substrate 70C, and liquid 55A. The lower substrate 60C includes an oil film 51C as a transmittance control layer.

The lower substrate 60C includes a first substrate 61C, first electrodes 62C, an insulating layer 64C, a water-repellent layer 67, the oil film 51C, and partitions 66. The first electrodes 62C are disposed above the first substrate 61C. The first electrodes 62C are arranged in a matrix (row-column configuration) in a plan view. The oil film 51C is disposed above the first electrodes 62C with the insulating layer 64C and the water-repellent layer 67 interposed therebetween. The water-repellent layer 67 is made of, for example, a resin material such as a fluoro-resin. The oil film 51C is disposed in the regions separated by the partitions 66. The regions separated by the partitions 66 correspond to the respective unit regions 52, and the transmittance can be controlled for each unit region 52.

The upper substrate 70C includes a second substrate 71C and a second electrode 73C. The second electrode 73C is disposed below the second substrate 71C. The second electrode 73C is disposed above the oil film 51C with the liquid 55A interposed therebetween. In other words, the liquid 55A and the oil film 51C are disposed between the first electrodes 62C and the second electrode 73C. The liquid 55A is, for example, water. The oil film 51C is colored in, for example, black. The transmittance control element 50D controls the transmittance of each unit region 52 by changing the state of the oil film 51C.

Specifically, the transmittance control element 50D according to the eighth embodiment changes the wettability between the water-repellent layer 67 and the liquid 55A in accordance with a voltage applied between the first electrodes 62C and the second electrode 73C. As illustrated in FIG. 14, the liquid 55A is not attracted to the water-repellent layer 67 in a state in which a voltage is not applied between the first electrodes 62C and the second electrode 73C. In this state, the oil film 51C entirely covers the water-repellent layer 67 in the regions separated by the partitions 66. At this time, because the display light L1 is absorbed by the oil film 51C, the transmittance of the unit regions 52 is reduced. Accordingly, the luminance of the display light L1 that has passed through the transmittance control element SOD is reduced.

As illustrated in FIG. 15, in a state in which a voltage is applied between the first electrodes 62C and the second electrode 73C, the wettability between the water-repellent layer 67 and the liquid 55A is changed, and the liquid 55A is attracted to the water-repellent layer 67. As a result, the oil film 51C moves so that a contact area between the oil film 51C and the water-repellent layer 67 is reduced. In this state, the display light L2 passes through a portion of the unit region 52 not covered with the oil film 51C, thereby preventing the transmittance of the unit region 52 from being lowered. Accordingly, the luminance of the display light L2 that has passed through the transmittance control element 50D is prevented from being lowered. This configuration can enhance contrast of the formed display image 101 by controlling the transmittances of the display light L1 and the display light L2.

The transmittance control element 50D is an electrowetting element and is excellent in responsiveness in controlling the transmittance compared to the liquid crystal elements described above. The transmittance control element 50D according to the eighth embodiment can be used for the display devices 1 and 1A to 1E according to the first to the fifth embodiments described above.

### Ninth Embodiment

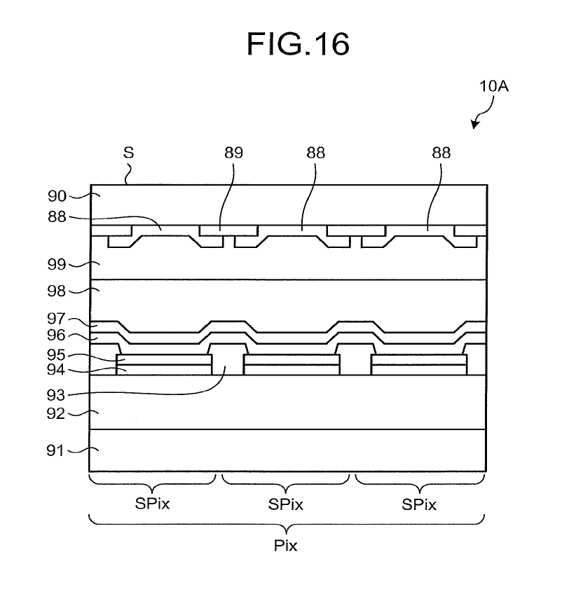

FIG. 16 is a sectional view schematically illustrating a sectional structure of a display portion according to a ninth embodiment of the present disclosure. This display portion 10A according to the ninth embodiment is a display panel using an organic light-emitting diode (OLED). This means that the display portion 10A has no lighting device 12 illustrated in FIG. 1.

As illustrated in FIG. 16, the display portion 10A includes a substrate 91, insulating layers 92 and 93, a reflective layer 94, lower electrodes 95, a self-luminous layer 96, an upper electrode 97, insulating layers 98 and 99, a color filter 88 as a color conversion layer, a black matrix 89 as a light-shielding layer, and a substrate 90. The substrate 91 is, for example, a semiconductor substrate made of silicon, a glass substrate, or a resin substrate. The substrate 91 includes, for example, a drive circuit, which is not illustrated, including switching elements such as TFTs.

The insulating layer 92 is a protective film for protecting the drive circuit and other elements, and can be made of silicon oxides, silicon nitrides, or the like. The lower electrodes 95 are anodes of the OLED and correspond to respective sub-pixels SPix. The lower electrodes 95 are made of a translucent conductive material such as ITO. The insulating layer 93 is referred to as a bank and sections the sub-pixels SPix. The reflective layer 94 is made of a material having metallic luster that reflects light from the self-luminous layer 96. The reflective layer 94 is made of, for example, silver, aluminum, or gold. The self-luminous layer 96 contains an organic material, and includes a hole injection layer, a hole transport layer, a luminous layer, an electron transport layer, and an electron injection layer, which are not illustrated.

The upper electrode 97 is made of a translucent conductive material such as ITO. The lower electrode 95 and the upper electrode 97 may be made of other translucent conductive materials such as indium zinc oxide (IZO) having compositions different from ITO. The upper electrode 97 is a cathode of the OLED. The insulating layer 98 is a sealing layer for sealing the upper electrode 97. The insulating layer 99 is a flattening layer for eliminating difference in level caused by the banks. The insulating layers 98 and 99 can be made of, for example, silicon oxides or silicon nitrides. The substrate 90 is a translucent substrate that protects the entire display portion 10A. The substrate 90 may be, for example, a glass substrate or a film resin substrate.

With this configuration, the light from the self-luminous layer 96 passes through the color filter 88 and is emitted from a display surface S of the substrate 90 to reach the eyes of the viewer. Controlling the intensity of light emitted from the self-luminous layer 96 for each sub-pixel SPix allows an image to be displayed on the display surface S.

The configuration of the display portion 10A is not limited to the example above, and the lower electrodes 95 may be cathodes and the upper electrode 97 may be an anode. In this case, polarities of the switching elements electrically coupled to the lower electrodes 95 can be changed as appropriate, and the stacking order of the carrier injection layers (hole injection layer and electron injection layer), carrier transport layers (hole transport layer and electron transport layer), and the luminescent layer can be changed as appropriate.

The display portion 10A may exclude the color filter 88. In this case, the self-luminous layer 96 contains different luminescent materials for the respective sub-pixels SPix to display light of red (R), light of green (G), and light of blue (B). The self-luminous layer 96 displaying red (R) corresponds to a sub-pixel SPix displaying red (R). The self-luminous layer 96 displaying green (G) corresponds to a sub-pixel SPix displaying green (G). The self-luminous layer 96 displaying blue (B) corresponds to a sub-pixel SPix displaying blue (B). With this configuration, the display portion 10A can display color images.

The display portion 10A according to the ninth embodiment can be used for the display devices 1 and 1A to 1E according to the first to the fifth embodiments described above. In addition, the display portion 10A according to the ninth embodiment can constitute a display device by combining the transmittance control element 50B of the sixth embodiment, the transmittance control element 50C of the seventh embodiment, and the transmittance control element 50D of the eighth embodiment described above.

While the exemplary embodiments according to the present disclosure has been described, the embodiments are not intended to limit the present disclosure. The contents disclosed in the embodiments are given by way of example only, and various changes may be made without departing from the spirit of the present disclosure. Appropriate changes made without departing from the spirit of the present disclosure naturally fall within the technical scope of the present disclosure.

For example, the display device according to the present disclosure includes the following aspects.

(1) A display device comprising:

a display portion configured to emit display light;

an optical element having a first surface and a second surface and configured to transmit or reflect the display light, the second surface being on an opposite side of the first surface and facing the display portion;

a reflective element facing the second surface of the optical element and configured to retroreflect the display light reflected at the optical element; and

a transmittance control element configured to transmit the display light at a different transmittance in accordance with a position at which the display light passes through the transmittance control element.

(2) The display device according to (1), wherein the transmittance control element faces the first surface of the optical element.
(3) The display device according to (1), wherein the transmittance control element faces the second surface of the optical element.
(4) The display device according to (1), wherein the transmittance control element faces a display surface of the display portion.
(5) The display device according to (1), wherein the transmittance control element faces a formed display image produced in the air close to the first surface of the optical element.
(6) The display device according to (1), wherein the transmittance control element faces the reflective element.
(7) The display device according to any one of (1) to (6), wherein

the transmittance control element is a liquid crystal element, and

the liquid crystal element includes a pair of substrates and a transmittance control layer disposed between the pair of substrates and containing liquid crystal molecules.

(8) The display device according to any one of (1) to (6), wherein

the transmittance control element is a guest-host liquid crystal element, and

the guest-host liquid crystal element includes: a pair of substrates; and a transmittance control layer disposed between the pair of substrates and containing dichroic dyes and liquid crystal molecules.

(9) The display device according to any one of (1) to (6), wherein the transmittance control element is an electrochromic element including a transmittance control layer having an optical property that changes in accordance with a voltage applied to the transmittance control element.
(10) The display device according to any one of (1) to (6), wherein

the transmittance control element is an electrowetting element,

the electrowetting element includes: a substrate; a water-repellent layer on the substrate; and a transmittance control layer on the water-repellent layer, and

a contact angle of the transmittance control layer to the water-repellent layer changes in accordance with a voltage applied to the electrowetting element.

(11) The display device according to any one of (1) to (10), further comprising:

a signal processor configured to:
output a video signal for controlling a display operation of the display portion to the display portion; and
output a control signal for controlling an operation of the transmittance control element in accordance with luminance information of the video signal to the transmittance control element; and

a driver configured to drive the transmittance control element in accordance with the control signal.

(12) The display device according to any one of (1) to (11), wherein the transmittance control element controls a transmittance of each of unit regions corresponding to respective pixels of the display portion.
(13) The display device according to any one of (1) to (11), wherein the transmittance control element controls a transmittance of each of unit regions sectioned at a greater pitch than a pitch of pixels of the display portion.

What is claimed is:

1. A display device comprising:
a display portion configured to emit display light;
an optical element having a first surface and a second surface and configured to transmit or reflect the display light, the second surface being on an opposite side of the first surface and facing the display portion;
a reflective element facing the second surface of the optical element and configured to retroreflect the display light reflected at the optical element; and
a transmittance control element configured to transmit the display light at a different transmittance in accordance with a position at which the display light passes through the transmittance control element.

2. The display device according to claim 1, wherein the transmittance control element faces the first surface of the optical element.

3. The display device according to claim 1, wherein the transmittance control element faces the second surface of the optical element.

4. The display device according to claim 1, wherein the transmittance control element faces a display surface of the display portion.

5. The display device according to claim 1, wherein the transmittance control element faces a formed display image produced in the air close to the first surface of the optical element.

6. The display device according to claim 1, wherein the transmittance control element faces the reflective element.

7. The display device according to claim 1, wherein
the transmittance control element is a liquid crystal element, and
the liquid crystal element includes a pair of substrates and a transmittance control layer disposed between the pair of substrates and containing liquid crystal molecules.

8. The display device according to claim 1, wherein
the transmittance control element is a guest-host liquid crystal element, and
the guest-host liquid crystal element includes: a pair of substrates; and a transmittance control layer disposed between the pair of substrates and containing dichroic dyes and liquid crystal molecules.

9. The display device according to claim 1, wherein the transmittance control element is an electrochromic element including a transmittance control layer having an optical property that changes in accordance with a voltage applied to the transmittance control element.

10. The display device according to claim 1, wherein
the transmittance control element is an electrowetting element,
the electrowetting element includes: a substrate; a water-repellent layer on the substrate; and a transmittance control layer on the water-repellent layer, and
a contact angle of the transmittance control layer to the water-repellent layer changes in accordance with a voltage applied to the electrowetting element.

11. The display device according to claim 1, further comprising:
a signal processor configured to:
output a video signal for controlling a display operation of the display portion to the display portion; and
output a control signal for controlling an operation of the transmittance control element in accordance with luminance information of the video signal to the transmittance control element; and
a driver configured to drive the transmittance control element in accordance with the control signal.

12. The display device according to claim 1, wherein the transmittance control element controls a transmittance of each of unit regions corresponding to respective pixels of the display portion.

13. The display device according to claim 1, wherein the transmittance control element controls a transmittance of each of unit regions sectioned at a greater pitch than a pitch of pixels of the display portion.
